(19) United States
(12) Patent Application Publication
(10) Pub. No.: US 2005/0266664 A1
(43) Pub. Date: Dec. 1, 2005

(54) Method for forming a fully silicided semiconductor device

(76) Inventors: Michael G. Harrison, Round Rock, TX (US); Olubunmi O. Adetutu, Austin, TX (US); Sam S. Garcia, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/857,726

(22) Filed: May 28, 2004

(51) Int. Cl. H01L 21/44

(52) U.S. Cl. 438/592; 438/682; 438/683; 438/664; 438/660

(57) ABSTRACT

A method for forming an improved fully silicided gate electrode in a semiconductor device in which the fully silicided gate electrode is formed using indirect heating. One embodiment relates to a method of manufacturing at least one semiconductor device. The method includes depositing silicon to a first thickness, depositing metal over the silicon, and indirectly heating the metal and silicon to form a metal silicide having a second thickness not less than the first thickness. Another embodiment relates to a method of manufacturing semiconductor devices, each semiconductor device having a fully silicided control electrode. The method includes providing a substrate, forming a dielectric layer over the substrate, forming a silicon-containing layer over the dielectric layer, depositing a metal-containing layer over the silicon-containing layer, and indirectly heating the metal-containing and silicon-containing layers to form a silicide layer in contact with the dielectric layer.

### FIELD OF THE INVENTION

This invention relates generally to semiconductor processing, and more specifically, to forming a fully silicided gate electrode in a semiconductor device.

### RELATED ART

As semiconductor technology advances, semiconductor devices are becoming increasingly smaller. However, this scaling down of devices may cause problems. For example, as gate oxides are scaled down, gate capacitance due to polysilicon depletion issues becomes more problematic, adversely affecting device performance. Therefore, one solution to this problem is the use of different metal gates for both N-type Metal-Oxide-Semiconductor (NMOS) and P-type Metal-Oxide-Semiconductor (PMOS) Field Effect Transistors (FETs) in a complimentary Metal-Oxide-Semiconductor (CMOS) technology as a replacement to polysilicon gates. However, the formation and integration of these dual metal gates is complex as compared to traditional doped polysilicon gates.

Therefore, instead of the formation of dual metal gates, one type of technology known today forms a fully silicided gate by using radiated heat during a rapid thermal anneal to fully silicide an amorphous silicon layer. However, this type of radiated heat provided during the rapid thermal anneal causes the silicide to react with and punch through the underlying gate dielectric and eventually react with the underlying silicon substrate. This interaction of the silicide with the gate dielectric and underlying silicon substrate results in a very low device yield. Therefore, a need exists for an improved method for forming fully silicided gates which allows for improved manufacturability and yield.

### BRIEF DESCRIPTION OF THE DRAWINGS

The present invention is illustrated by way of example and is not limited by the accompanying figures, in which like references indicate similar elements.

FIGS. 1-4 illustrate cross-sectional views of a semiconductor device at different processing stages in accordance with one embodiment of the present invention;

FIGS. 5-8 illustrates cross-sectional views of a semiconductor device at different processing stages in accordance with an alternate embodiment of the present invention; and

FIG. 9 illustrates a flow diagram for forming a fully silicided gate electrode in a semiconductor device, in accordance with one embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

One embodiment of the present invention relates to forming a fully silicided gate electrode in a semiconductor device using indirect heating. As used herein, indirect heating refers to heating via a transfer medium such as air, water, metal, gases, etc. For example, indirect heating includes heating an object by conduction (which includes heating the object via physical contact with that object) and heating by convection (which includes heating the object via air or other gases). Therefore, indirect heating substantially excludes radiative heating which is direct heating and does not require a transfer medium. That is, radiated heat generates its own medium by projecting waves/particles upon an object to be heated, thus directly heating the object.

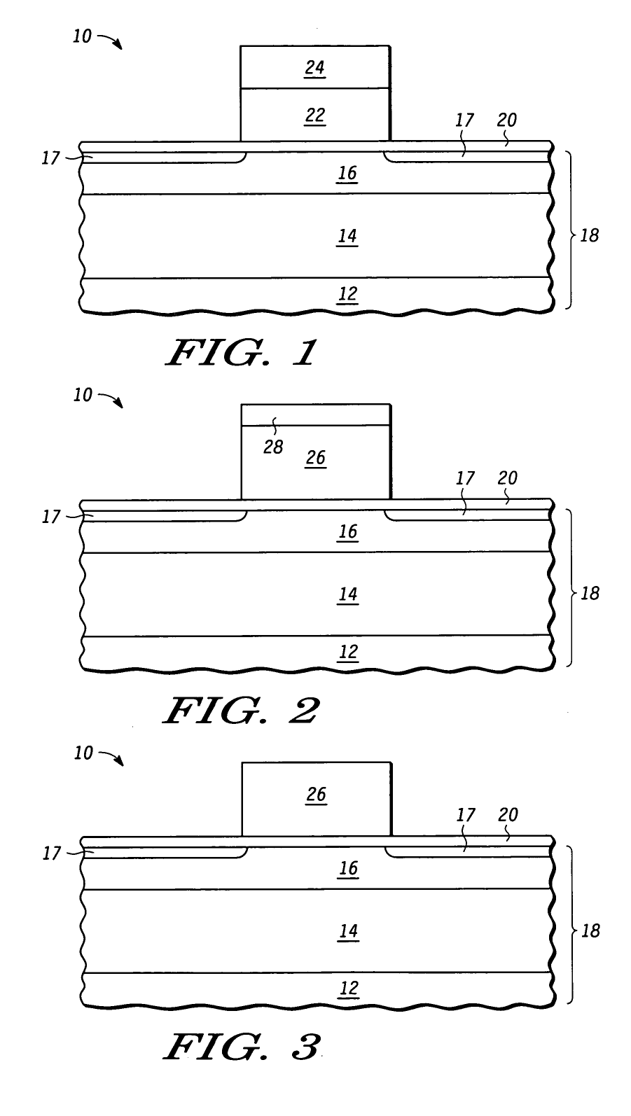

FIG. 1 illustrates a semiconductor device 10 having a semiconductor layer 12, an insulator layer 14 overlying semiconductor layer 12, a semiconductor layer 16 overlying insulator layer 14, a gate dielectric layer 20 overlying semiconductor layer 16, a patterned silicon-containing layer 22 overlying gate dielectric layer 20, and a patterned metal layer 24 overlying patterned silicon-containing layer 22. In one embodiment, semiconductor layer 12, insulator layer 14, and semiconductor layer 16 form a portion of a Silicon-On-Insulator (SOI) wafer 18. Note that in alternate embodiments, wafer 18 may be a bulk semiconductor wafer, in which insulator layer 14 and semiconductor layer 12 are not present. In this embodiment, semiconductor layer 16 may be thicker since layers 14 and 12 are not present. In one embodiment, semiconductor layer 16 can be any type of semiconductor material, such as, for example, silicon, gallium arsenide, silicon germanium, monocrystalline silicon, the like, or any combination thereof. Semiconductor layer 16 includes source/drain extensions 17 laterally adjacent the sides of patterned silicon-containing layer 22 and metal layer 24.

Still referring to FIG. 1, note that a silicon-containing layer may be blanket deposited over gate dielectric layer 20 and a metal layer may be blanket deposited over the silicon layer. The blanket deposited silicon-containing layer and metal layer can be patterned and etched to form silicon-containing layer 22 and metal layer 24. In this embodiment, an anti-reflective coating (ARC) may also be formed over the metal layer prior to patterning and etching to form silicon-containing layer 22 and metal layer 24 (where this ARC layer is then removed after patterning). Also note that additional conductive layers may be present on metal layer 24. These additional conductive layers may be present in addition to the ARC layer. (Note that in an alternate embodiment, silicon layer 22 and metal layer 24 may not yet be patterned. In this alternate embodiment, source/drain extensions 17 may not yet be formed.)

In one embodiment, silicon-containing layer 22 may include, for example, amorphous silicon or polysilicon. Alternatively, silicon-containing layer 22 may include other silicon-containing materials such as, for example, silicon germanium. Also, silicon-containing layer 22 may be doped to form different types of devices or transistors, such as, for example, a PMOS device or NMOS device. For example, if semiconductor device 10 is to be a PMOS device, silicon-containing layer 22 may be doped with boron, and if semiconductor device 10 is to be an NMOS device, silicon-containing layer 22 may be doped with phosphorous, arsenic, and antimony. In one embodiment, the doping may be performed through implanting, or alternatively, the doping may be formed in-situ during the deposition of silicon-containing layer 22. In alternate embodiments, silicon-containing layer 22 may not be doped.

In one embodiment, gate dielectric layer 20 includes any appropriate type of insulating materials, such as, for example, silicon oxides, silicon oxy-nitrides, silicon nitrides, metal oxides, metal silicates, metal silicon oxy-nitrides, metal nitrides, and combinations thereof. Metal layer 24 may be any metal-containing layer. For example, metal layer 24 may include a metal such as, for example, nickel, cobalt, titanium, tungsten, hafnium, etc, or any combination thereof. Therefore, in one embodiment, metal layer 24 may include any transitional metal, or combination thereof. Also, note that in one embodiment, the thickness of metal layer 24 is approximately the same or thicker than the thickness of silicon-containing layer 22.

FIG. 2 illustrates semiconductor device 10 after indirectly heating semiconductor wafer 18 to form a metal silicide 26, where the metal silicide 26 is in contact with gate dielectric 20 (e.g. at least a portion of metal silicide 26 is in contact with at least a portion of gate dielectric 20). During the indirect heating, metal layer 24 reacts with silicon-containing layer 22 to form metal silicide 26 which is in contact with gate dielectric layer 20. Since metal layer 24 reacts with silicon-containing layer 22 down to gate dielectric layer 20, such that at least a portion of metal silicide 26 is in contact with gate dielectric 20, metal silicide 26 may be referred to as a gate stack, a fully silicided gate stack, or a control electrode stack. Therefore, metal silicide 26 may be used to form a fully silicided gate electrode for semiconductor device 10. Also, note that a thickness of metal silicide 26 is not less than a thickness of silicon-containing layer 22. In one embodiment, in which metal layer 24 is nickel, metal silicide 26 is a nickel silicide.

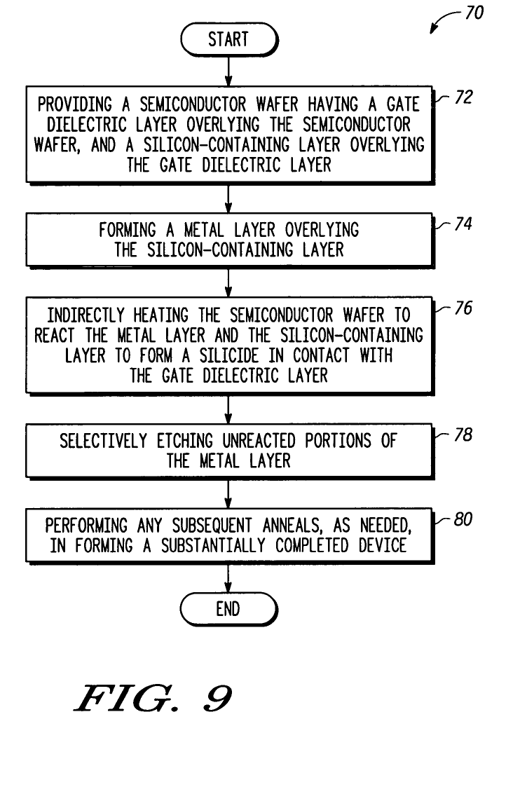

FIG. 2 also includes a remaining portion of unreacted metal 28 which includes unreacted portions of metal layer 24. Note that in alternate embodiments, an unreacted portion of metal layer 24 may not be present after the indirect heating. Note that different embodiments for applying the indirect heating will be discussed in reference to FIG. 9 below.

FIG. 3 illustrates semiconductor device 10 after removal of unreacted metal 28 using, for example, a wet etch. Note that the removal of unreacted metal 28 is optional. Furthermore, note that if unreacted metal 28 is not present after the formation of metal silicide 26, removal of unreacted metal 28 is not necessary.

In the alternate embodiment in which silicon-containing layer 22 and metal layer 24 of FIG. 1 were not yet patterned, metal silicide layer 26 may be patterned and etched after the indirect heating of FIG. 2 to form metal silicide layer 26 and the optional removal of unreacted metal 28.

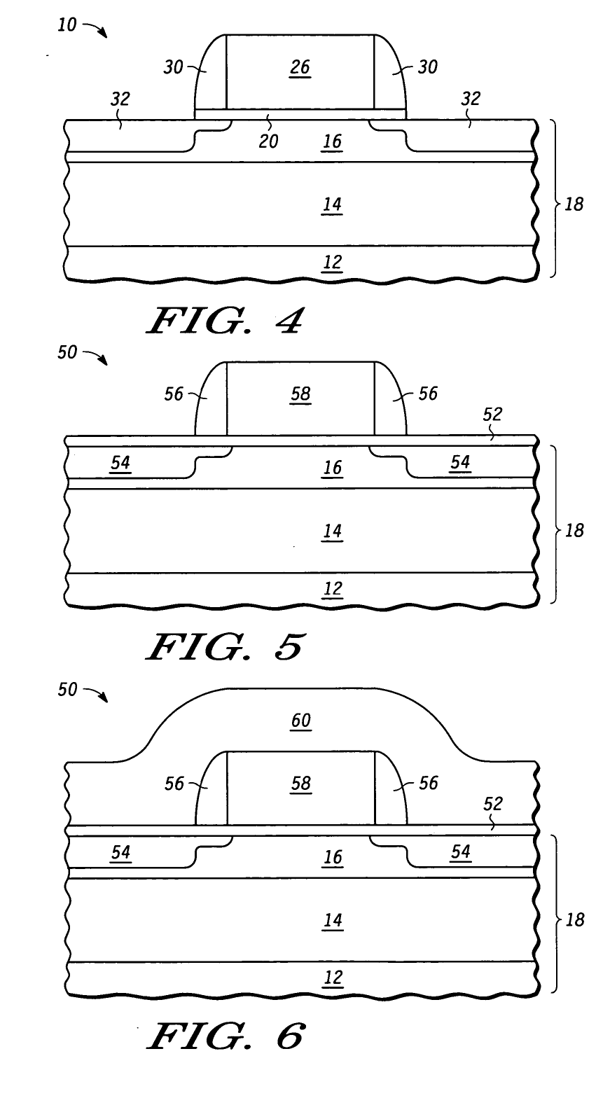

FIG. 4 illustrates semiconductor device 10 after formation of sidewall spacers 30 adjacent metal silicide 26, removal of portions of gate dielectric layer 20, and formation of source/drain regions 32 (also referred to as current electrode regions 32) in semiconductor layer 16, each including an extension portion and a deep implant portion and each being in semiconductor layer 16 proximate metal silicide 26 (i.e. the control electrode stack). Therefore, in the processing stage of FIG. 4, semiconductor device 10 is a substantially completed device or transistor. Therefore, in the illustrated embodiment, metal silicide 26 may be referred to as a fully silicided gate electrode.

FIGS. 5-8 illustrate formation of a semiconductor device 50 having a fully silicided gate stack in accordance with another embodiment of the present invention. FIG. 5 includes semiconductor device 50 having a gate dielectric layer overlying semiconductor layer 16, a silicon-containing layer 58 (also referred to as a silicon-containing gate stack 58) overlying gate dielectric layer 52, and sidewall spacers 56 overlying gate dielectric layer 52 and adjacent gate stack 58. Semiconductor layer 16 also includes source/drain regions 54 (also referred to as current electrode regions 54) which each include an extension region and a deep implant region and are each proximate gate stack 58. Note that the descriptions are provided above for semiconductor layers 12 and 16, insulator layer 14, and wafer 18. Also, note that the same descriptions provided above for the materials of gate dielectric 20 also apply to gate dielectric 52. Similarly, the same descriptions and dopants provided above for silicon-containing layer 22 also apply to silicon-containing layer 58.

FIG. 6 illustrates semiconductor device 50 after formation of a metal layer 60 overlying gate dielectric layer 52, spacers 52, and silicon-containing layer 58. In one embodiment, metal layer 60 is blanket deposited over wafer 18. Note that the materials provided above for metal layer 24 also apply to metal layer 60. Also, note that in one embodiment, the thickness of metal layer 60 is approximately the same or thicker than the thickness of silicon-containing layer 58.

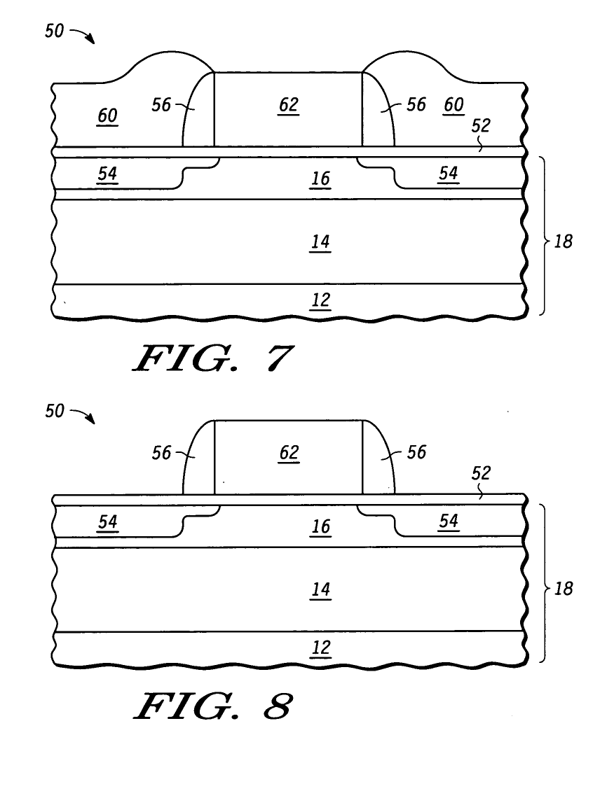

FIG. 7 illustrates semiconductor device 50 after indirectly heating semiconductor wafer 18 to form a metal silicide 62 between spacers 56, where at least a portion of metal silicide 62 is in contact with gate dielectric layer 52. During the indirect heating, a portion of metal layer 60 overlying silicon-containing layer 58 reacts with silicon-containing layer 58 to form metal silicide 62 which is in contact with gate dielectric layer 52. Since metal layer 60 reacts with silicon-containing layer 58 down to gate dielectric layer 52, such that at least a portion of metal silicide 62 is in contact with gate dielectric layer 52, metal silicide 62 may be referred to as a gate stack, a fully silicided gate stack, or a control electrode stack. Therefore, metal silicide 62 may be used to form a fully silicided gate electrode for semiconductor device 50. Also, note that a thickness of metal silicide 62 is not less than a thickness of silicon-containing layer 58. Also note that portions of metal layer 60 overlying gate dielectric layer 52 remain after reaction of metal layer 60 to form metal silicide 62. In an alternate embodiment (not illustrated) portions of unreacted metal may also remain overlying metal silicide 62.

FIG. 8 illustrates semiconductor device 50 after removal of any remaining portions of metal layer 60 (i.e. removal of unreacted portions of metal layer 60). These unreacted portions may include those unreacted portions overlying gate dielectric layer 52 and metal silicide 62, if any. Therefore, in the processing stage of FIG. 8, semiconductor device 50 is a substantially completed device or transistor. Therefore, in the illustrated embodiment, metal silicide 62 may be referred to as a fully silicided gate electrode.

FIG. 9 illustrates a flow diagram 70 for forming a fully silicided gate electrode in a semiconductor device, in accordance to one embodiment of the present invention. Flow 70 begins with block 72 in which a semiconductor wafer is provided having a gate dielectric layer overlying the semiconductor wafer, and a silicon-containing layer overlying the gate dielectric layer. For example, this may refer to wafer 18, gate dielectric layer 20, and silicon-containing layer 22 of FIG. 1 or to wafer 18, gate dielectric layer 52, and silicon-containing layer 58 of FIG. 5.

After block 72, flow proceeds to block 74 in which a metal layer is formed overlying the silicon-containing layer. In one embodiment, the metal layer is deposited over the silicon-containing layer. For example, block 74 may refer to the formation of metal layer 24 in FIG. 1 or the formation of metal layer 60 in FIG. 6.

After block 74, flow proceeds to block 76 in which the semiconductor wafer is indirectly heated to react the metal layer and the silicon-containing layer to form a metal silicide in contact with the gate dielectric layer. For example, this may refer to the formation of metal silicide 26 in FIG. 4 or the formation of metal silicide 62 in FIG. 7, both of which were described in more detail above. Note that when indirectly heating the semiconductor wafer, the silicon-containing layer and the metal layer are also heated. In one embodiment, indirectly heating the semiconductor wafer includes heating the chuck, susceptor, or other support device upon which the semiconductor wafer sits. This may be referred to as conductive heating in which the semiconductor wafer is heated primarily via conductive heating. For example, in reference to either FIG. 4 or FIG. 7, semiconductor wafer 18 may sit on (and thus be supported by) a chuck that is heated, thus indirectly heating semiconductor wafer 18. (Although the descriptions of block 76 are being discussed in reference to a chuck, note that discussions also apply to the use a susceptor or other support device.) In one embodiment, the chuck is heated to a temperature in a range of approximately 150 degrees Celsius to 900 degrees Celsius, or more preferably, to a temperature in a range of approximately 200 degrees Celsius to 600 degrees Celsius, or, even more preferably, to a temperature in a range of approximately 300 degrees Celsius to 450 degrees Celsius. In one embodiment, the chuck is heated to approximately 360 degrees Celsius. Note that the chuck may be heated to a particular temperature or temperature range; however, the semiconductor wafer itself may not be heated to the full temperature of the chuck. In one embodiment, the chuck is heated to the desired temperature prior to placing the semiconductor wafer. In one embodiment, the semiconductor wafer is indirectly heated on the heated chuck for a predetermined amount of time. That is, in one embodiment, the semiconductor wafer is placed in thermally conductive contact with the device supporting the wafer (e.g. the chuck) for this predetermined amount of time. In one embodiment, this predetermined amount of time is in a range of 10 to 200 seconds, or, more preferably, for 20 to 60 seconds. Therefore, in one embodiment, this time may be measured from the time the semiconductor wafer is placed on the heated chuck to the time it is removed.

In one embodiment, the metal layer may be deposited at room temperature. In an alternate embodiment, the metal layer may be formed while the semiconductor wafer sits on the heated chuck. In one embodiment, the metal layer may be formed prior to indirectly heating the semiconductor wafer, but without breaking vacuum between formation of the metal layer and indirectly heating the semiconductor wafer.

In one embodiment, indirectly heating the semiconductor wafer includes heating the semiconductor wafer within a furnace. This may be referred to as convective heating in which the semiconductor wafer is heated primarily via convective heating. For example, as discussed in reference to either FIG. 2 or FIG. 7, semiconductor wafer 18 may be placed in a furnace, thus indirectly heating semiconductor wafer 18. In one embodiment, the furnace is heated to a temperature in a range of approximately 150 degrees Celsius to 900 degrees Celsius, or more preferably, to a temperature in a range of approximately 200 degrees Celsius to 600 degrees Celsius, or, even more preferably, to a temperature in a range of approximately 300 degrees Celsius to 450 degrees Celsius. In one embodiment, the furnace is heated to approximately 360 degrees Celsius. Note that the furnace may be heated to a particular temperature or temperature range; however, the semiconductor wafer itself may not be heated to the full temperature of the furnace. In one embodiment, the furnace is heated to the desired temperature with the semiconductor wafer inside. In one embodiment, once the furnace reaches the desired temperature, the semiconductor wafer is heated in the furnace for a predetermined amount of time. In one embodiment, this predetermined amount of time is in a range of 15 minutes to 1 hour.

Note that in alternate embodiments, other methods of indirectly heating via conductive or convection heating may also be used to form the metal silicide. As a result of the indirect heating, a fully silicided gate stack may be formed without reacting with the underlying gate dielectric and without punching through the underlying gate dielectric to react with the underlying semiconductor layer.

After indirectly heating the semiconductor wafer, flow proceeds to block 78 in which unreacted portions of the metal layer are selectively etched using, for example, a wet etch. For example, this may refer to the selective etching of remaining metal portion 28 in FIG. 2 or the remaining portions of metal layer 60 in FIG. 7. Note that the removal of these unreacted portions of the metal layer, if present, is optional.

Flow then proceeds to block 80 where processing is completed to form a substantially completed device. During this processing, any subsequent anneals are performed, as needed. However, note that the fully silicided gate stack has already been formed, therefore, subsequent anneals using, for example, indirect heating (such as conductive or convective heating) or direct heating (such as radiative heating, including, for example, rapid thermal anneals) may be performed without damaging the underlying gate dielectric. Also note that in alternate embodiments (not shown in FIGS. 1-8), additional devices may be formed where, for example, a plurality of fully silicided devices may be formed. These plurality of devices may include both NMOS and PMOS fully silicided devices.

By now it should be appreciated that there has been provided a method for forming an improved fully silicided gate electrode in a semiconductor device in which the fully silicided gate electrode is formed using indirect heating. For example, one embodiment relates to a method of manufacturing at least one semiconductor device. The method includes depositing silicon to a first thickness, depositing metal over the silicon, and indirectly heating the metal and silicon to form a metal silicide having a second thickness not less than the first thickness. Another embodiment relates to a method of manufacturing semiconductor devices, each semiconductor device having a fully silicided control electrode. The method includes providing a substrate, forming a dielectric layer over the substrate, forming a silicon-containing layer over the dielectric layer, depositing a metal-containing layer over the silicon-containing layer, and indirectly heating the metal-containing and silicon-containing layers to form a silicide layer in contact with the dielectric layer.

In the foregoing specification, the invention has been described with reference to specific embodiments. However, one of ordinary skill in the art appreciates that various modifications and changes can be made without departing from the scope of the present invention as set forth in the claims below. For example, the formation of a metal silicide, such as was described above in reference to metal silicides 26 and 62, may also apply to vertical transistors or Fin FETs. That is, a gate of a vertical transistor or Fin FET may be fully silicided such that a metal silicide is formed in contact with a gate dielectric of the device. The formation of this fully silicided gate may be formed, for example, through the formation of a metal-containing layer and a silicon-containing layer, as described in reference to various embodiments above. Accordingly, the specification and figures are to be regarded in an illustrative rather than a restrictive sense, and all such modifications are intended to be included within the scope of the present invention.

Although the invention has been described with respect to specific conductivity types or polarity of potentials, skilled artisans appreciated that conductivity types and polarities of potentials may be reversed.

Moreover, the terms “front”, “back”, “top”, “bottom”, “over”, “under”, “up”, and “down” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one.

The term “plurality”, as used herein, is defined as two or more than two. The term another, as used herein, is defined as at least a second or more.

The term “coupled”, as used herein, is defined as connected, although not necessarily directly, and not necessarily mechanically.

1. A method of manufacturing at least one semiconductor device, the method comprising:
depositing silicon to a first thickness;
depositing metal over the silicon; and
indirectly heating the metal and silicon to form a metal silicide having a second thickness not less than the first thickness.

2. The method of claim 1 wherein the indirect heating is performed while the metal is being deposited over the silicon.

3. The method of claim 1 wherein the indirect heating is performed after the metal has been deposited over the silicon.

4. The method of claim 1 wherein the indirect heating comprises at least one of the group consisting of conductive heating and convective heating.

5. The method of claim 4 wherein
a wafer includes the silicon and the metal, and
the indirect heating comprises convectively heating the wafer in a furnace at a temperature greater than 150° C. and less than 900° C. degrees.

6. The method of claim 1 wherein
a wafer includes the silicon and the metal, and
the indirect heating comprises heating a device for supporting the wafer to a temperature greater than 150° C. and less than 900° C. degrees.

7. The method of claim 5 wherein the device is heated to a temperature between 200° C. and 600° C.

8. The method of claim 7 further comprising:
placing the wafer in thermally conductive contact with the device supporting the wafer for at least 10 seconds but no longer than 200 seconds.

9. The method of claim 7 wherein the wafer is indirectly heated for at least 20 seconds but no longer than 60 seconds.

10. The method of claim 1 further comprising:
depositing a dielectric before depositing the silicon, wherein the silicon is deposited on the dielectric, and the metal silicide region is in contact with the dielectric.

11. The method of claim 1 further comprising:
heating the metal silicide region using at least one of conductive heating, convection heating and radiative heating.

12. The method of claim 11 wherein
the heating of the metal and silicon comprises conductive heating; and
the heating of the metal silicide comprises direct heating using a rapid thermal anneal.

13. The method of claim 12 wherein the heating of the metal and silicon comprises:
heating a chuck; and
conducting heat from the chuck to the metal and silicon.

14. The method of claim 1 further comprising:
removing portions of at least one of the silicon and the metal before the heating of the silicon and metal to form a portion of the semiconductor device.

15. The method of claim 1 further comprising:
removing portions of the metal silicide to form a control electrode stack for the semiconductor device.

16. The method of claim 1 wherein the semiconductor device comprises a transistor, the method further comprising:
removing portions of the metal after indirectly heating the silicon and the metal, to form a gate stack comprising the metal silicide for the transistor.

17. The method of claim 1 wherein the metal is a transition metal.

18. The method of claim 1 wherein the metal is one of the group consisting of nickel, cobalt, titanium, tungsten, platinum, palladium, iridium, ruthenium and hafnium.

19. An apparatus manufactured by the method of claim 1.

20. A method of manufacturing a semiconductor device having a fully silicided control electrode, the method comprising:
providing a substrate;
forming a dielectric layer over the substrate;
forming a silicon-containing layer over the dielectric layer;
depositing a metal-containing layer over the silicon-containing layer; and
indirectly heating the metal-containing and silicon-containing layers to form a silicide layer in contact with the dielectric layer.

21. The method of claim 20 further comprising:
removing unreacted metal from over the silicide layer after indirectly heating the metal-containing and silicon-containing layers.

22. The method of claim 20 further comprising:
removing portions of at least one of the group consisting of the silicon-containing layer, the metal-containing layer, and the silicide layer, to form a control electrode stack; and
forming current electrode regions in the substrate proximate to the control electrode stack.

23. The method of claim 22 wherein the forming the silicon-containing layer comprises:
incorporating a first dopant in the silicon-containing layer if the semiconductor device comprises a first type of transistor; and
incorporating a second dopant, different from the first dopant, in the silicon-containing layer if the semiconductor device comprises a second type of transistor.

24. An apparatus manufactured by the method of claim 23.

25. The method of claim 23 further comprising directly heating the silicide layer.

26. The method of claim 20 wherein the silicon-containing layer is formed on the dielectric layer and the metal-containing layer is formed on the silicon-containing layer.

27. The method of claim 20 wherein the silicon-containing layer comprises one of the group consisting of polysilicon and silicon-germanium.

28. The method of claim 20 wherein the step of indirectly heating comprises:
supporting the substrate on a susceptor; and
heating the susceptor.

29. The method of claim 28 wherein the step of indirectly heating further comprises:
heating the susceptor to a temperature greater than 200° C. and less than 600° C. degrees; and
placing the substrate in thermal contact with the susceptor for more than 10 second and less than 60 seconds.

30. An apparatus manufactured by the method of claim 20.
